(19) United States
(12) Patent Application Publication
(10) Pub. No.: US 2009/0095971 A1
(43) Pub. Date: Apr. 16, 2009

(54) WIRE BOND LED LIGHTING UNIT

(76) Inventors: Andrew Glovatsky, Plymouth, MI (US); Harvinder Singh, Shelby Twp., MI (US)

Correspondence Address: FRASER CLEMENS MARTIN & MILLER LLC, 28366 KENSINGTON LANE, PERRYSBURG, OH, 43551, US

(21) Appl. No.: 11/873,021

(22) Filed: Oct. 16, 2007

(51) Int. Cl. H01L 33/00

(52) U.S. Cl. 257/99; 257/E33.001

(57) ABSTRACT

A wire bond LED lighting unit and method for maximizing heat transfer in an LED lighting unit are disclosed, wherein the LED lighting unit includes an LED package disposed on a first carrier plate and is in thermal communication therewith. A PWB is disposed on the first carrier plate spaced from the LED package. The LED package is in electrical communication with the PWB. The first carrier plate is also in thermal communication with the PWB.

### FIELD OF THE INVENTION

This invention relates to a lighting unit. More particularly, the invention is directed to a modular LED lighting unit and method for maximizing heat transfer in the LED lighting Unit.

### BACKGROUND OF THE INVENTION

Light emitting diodes (LED's) are increasingly being used in a wide variety of applications including vehicle lighting, flashlights, traffic signals, backlighting, and emergency lighting, for example. LED packages are energy efficient, reliable, and long lasting, making a lighting unit that incorporates an LED package, desirable in many high volume applications.

However, LED performance largely depends on the ambient temperature of the operating environment. Driving an LED in high ambient temperatures may result in overheating of the LED package, eventually leading to device failure. Providing an adequate heat-sink is required to maintain long life. This is especially important when considering automotive, medical, and military applications, where the device must operate over a large range of temperatures, and are required to have a low failure rate. Typically, some LED packages that are soldered to a substrate cannot survive in environments with an operating temperature range of −40 to 125 degrees Celsius or higher. Solder joints quickly fatigue due to the LED package's low coefficient of thermal expansion (CTE), the high CTE of the substrate, and the modulus difference between the LED and the substrate. Specifically, the LED package and the substrate do not expand and contract equally during a change in temperature. Where the LED package is directly soldered to the substrate, the solder joints fatigue, disrupting the operation of the LED package. Additionally, environmental factors such as vibration and the thermal energy from the LED contribute to the degradation of the solder joints.

Heat generated by the LED and internal circuitry is primarily dissipated through a base of the LED package. Thus, it is important that an efficient thermal contact is made to the base of the package. Currently, this issue is solved by the use of high cost insulated metal core substrates (IMC) or high temperature flexible substrates. The LED in these cases is either soldered or wire bonded to the substrate for electrical interconnection and thermally bonded to the substrate to dissipate heat from the base of the LED package. These substrate technologies make the design cost prohibitive for LED forward lighting applications.

It would be desirable to have a wire bond LED lighting unit and method for maximizing heat transfer in an LED lighting unit, wherein the LED lighting unit is cost-efficient and reliable for variable temperature applications.

### SUMMARY OF THE INVENTION

Concordant and consistent with the present invention, a wire bond LED lighting unit and method for maximizing heat transfer in an LED lighting unit, wherein the LED lighting unit is cost-effective and reliable for variable temperature applications, has surprisingly been discovered.

In one embodiment, an LED lighting unit comprises a first carrier plate; an LED package in thermal communication with the first carrier plate; and a PWB disposed on the first carrier plate and in electrical communication with the LED package, wherein the PWB is spaced from at least a portion of the LED package.

In another embodiment, an LED lighting unit comprises a first carrier plate; an LED package in thermal communication with the first carrier plate; a PWB disposed on the first carrier plate and in electrical communication with the LED package, wherein the PWB is spaced from at least a portion of the LED package; and a surface-mount device connector disposed on the PWB, the surface-mount device connector in electrical communication with the PWB.

The invention also provides methods for maximizing heat transfer in an LED lighting unit.

One method comprises the steps of providing an LED package; attaching the LED package to a first carrier plate to provide thermal communication between the LED package and the first carrier plate; disposing a PWB on the first carrier plate, wherein the PWB is at least partially spaced from the LED package; and providing electrical communication between the PWB and the LED package.

### BRIEF DESCRIPTION OF THE DRAWINGS

The above, as well as other advantages of the present invention, will become readily apparent to those skilled in the art from the following detailed description of the preferred embodiment when considered in the light of the accompanying drawings in which:

FIG. 1 is a top plan view of an LED lighting unit according to an embodiment of the present invention; and

FIG. 2 is a sectional view of the LED lighting unit illustrated in FIG. 1 taken along line 2-2.

### DETAILED DESCRIPTION OF EXEMPLARY EMBODIMENTS OF THE INVENTION

The following detailed description and appended drawings describe and illustrate various embodiments of the invention. The description and drawings serve to enable one skilled in the art to make and use the invention, and are not intended to limit the scope of the invention in any manner. In respect of the methods disclosed, the steps presented are exemplary in nature, and thus, the order of the steps is not necessary or critical.

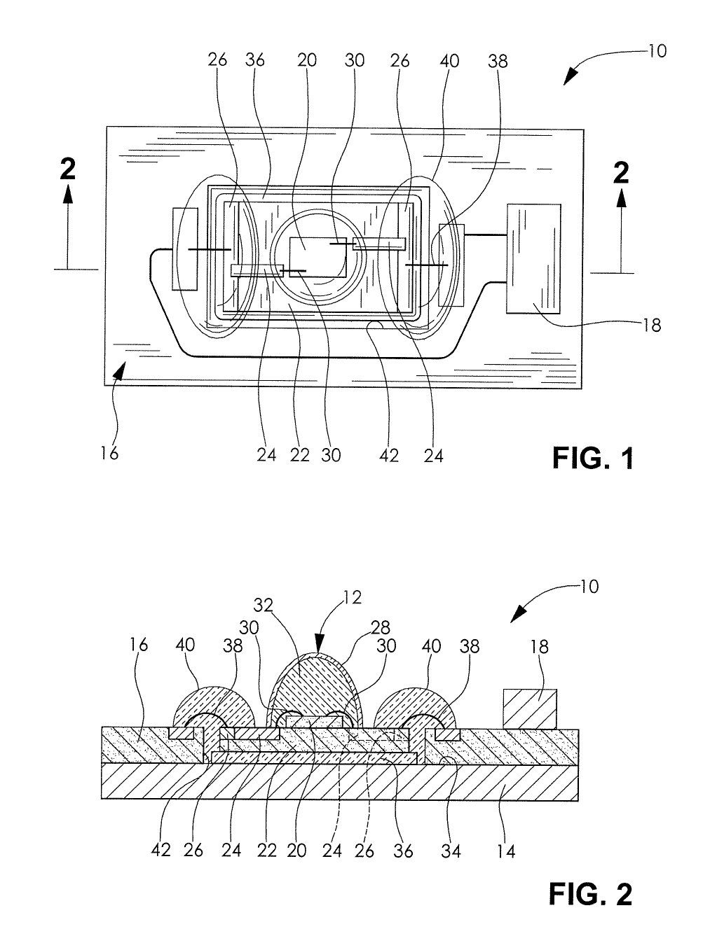

FIGS. 1 and 2 show a modular LED lighting unit 10 according to an embodiment of the present invention. The LED lighting unit 10 comprises an LED package 12, a first carrier plate 14, a printed wiring board (PWB) 16, and a surface-mount device connector 18 (hereinafter referred to as an SMD connector).

In the embodiment shown, the LED package 12 includes an LED die 20, a second carrier plate 22, a plurality of conductive traces 24, a secondary wire bond surface 26, and a dome 28. The LED die 20 is disposed on the second carrier plate 22 to provide thermal communication therebetween. It is understood that the LED die 20 may be thermally connected to the second carrier plate using any conventional material such as thermal interface materiel, for example. The conductive traces 24 are disposed on the second carrier plate 22 and provide electrical communication between the LED die 20 and the secondary wire bond surface 26. It is understood that the conductive traces may be any size or shape. As shown, a plurality of first wire bonds 30 provides electrical communication between the LED die 20 and the plurality of conductive traces 24. It is understood that electrical communication between the LED die 20 and the conductive traces 24 may be provided using any conventional technique such as thermocompression, ball bonds, ribbon bonds, and C4 bonds, for example. A first potting material 32 is disposed on the LED die 20, the first potting material encasing the LED die 20 and the first wire bonds 30 connecting the LED die 20 to the conductive traces 24. The first potting material may be any conventional potting material, such as, low modulus silicon, for example. The first potting material 32, the LED die 20 and a portion of the conductive traces 24 are further enclosed by the dome 28. The dome 28 may be prepared from any conventional material used in LED packages 12 such as a clear glass, a colored glass, and a reflective material. Alternatively, the potting material can be eliminated, thereby leaving a cavity between the dome 28 and the second carrier plate 22. It is understood that the LED die 20, the conductive traces 24, and the secondary wire bond surface 26 are in thermal communication with the second carrier plate 22. The second carrier plate 22 is formed from a thermally conductive material such as ceramic, for example.

The LED package 12 is disposed on a first face 34 of the first carrier plate 14 with a circumference of the LED package 12 spaced from at least a portion of the PWB 16. The first carrier plate 14 may be prepared from any conventional thermally conductive material such as aluminum for example. A thermal adhesive 36 is disposed between the LED package 12 and the first carrier plate 14 to attach the LED package 12 to the first carrier plate 14. It is understood that the thermal adhesive may be replaced by a thermal interface material such as thermal grease and phase change material, for example. The thermal adhesive 36 provides thermal communication between the LED package 12 and the first carrier plate 14 and further provides a mechanical coupling between the LED package and the first carrier plate 14. The first carrier plate 14 is adapted to receive a plurality of fasteners (not shown) such as screws, for example. The fasteners provide a means of attachment between the PWB 16 and the first carrier plate 14. It is understood that the first carrier plate 14 may be adapted to provide thermal communication between the LED package 12 and a secondary heat-sink system (not shown).

The PWB 16, also referred to as a printed circuit board, may be formed from any conventional PWB 16 material such as FR4, for example. The PWB 16 abuts the first face 34 of the first carrier plate 14 and is spaced from at least a portion of the LED package 12. In the embodiment shown, the PWB 16 includes an aperture 42. It is understood that PWB 16 may include additional apertures to provide a means for coupling a plurality of optical lenses (not shown) to the PWB 16. The plurality of optical lenses provides a means to focus or disperse the light emitted from the LED package 12. The plurality of optical lenses may be prepared from any conventional lens material such as glass or plastic, for example.

The aperture 42 receives the LED package 12 therein and allows the LED package 12 to extend therethrough, while maintaining a space between the PWB 16 and the LED package 12. A second plurality of wire bonds 38 provides electrical communication between the PWB 16 and the secondary wire bond surface 26 of the LED package 12. A second potting material 40 is selectively added to encapsulate the second plurality of wire bonds 38 between the PWB 16 and the LED package 12. The second potting material 40 may be any conventional potting material such as low modulus silicon, for example. The SMD connector 18 is disposed on the PWB 16 and is in electrical communication therewith. The SMD connector 18 provides electrical communication between the PWB 16 and a source of electrical power (not shown) such as a battery, for example.

In use, electrical current travels through the SMD connector 18, the PWB 16, the second plurality of wire bonds 38, the conductive traces 24, and the first plurality of wire bonds 30 of the LED package 12. When current passes through the LED package 12, the LED package 12 radiates both light and heat. The heat from the LED package 12 and the surrounding circuitry dissipates through the second carrier plate 22, the thermal adhesive 36, and the first carrier plate 14. The PWB 16 is also in thermal communication with the first carrier plate 14. Heat generated by the PWB 16 is dissipated directly through the first carrier plate 14. It is understood that the first potting material 32 and the second potting material 40 protect the wire bonds 30, 38 from potentially damaging conditions such as moisture, various corrosive chemicals, excessive heat, vibration, mechanical impact, thermal shocks, and abrasion which might occur while the LED package 12 is in operation.

The LED lighting unit 10 and method according to the present invention maximizes a heat transfer rate from the LED package 12 and surrounding circuitry and militates against failure due to variable temperature applications. Specifically, the LED package 12 is spaced from the PWB 16. Since the LED package 12 has a CTE differing from the PWB 16, failure due to fatigue is militated against. Spacing the LED package 12 from the PWB 16 also allows the use of lower cost PWB 16, rather than a higher cost insulted metal circuit board (not shown). Additionally, spacing the LED package 12 from the PWB 16 maximizes heat transfer by coupling the LED package 12 directly to the first carrier plate 14 with a thermal adhesive 36. The use of wire bonding associated with the electrical connections facilitates spacing the LED package 12 from the PWB 16, while providing electrical communication between the PWB 16 and the LED package 12.

From the foregoing description, one ordinarily skilled in the art can easily ascertain the essential characteristics of this invention and, without departing from the spirit and scope thereof, make various changes and modifications to the invention to adapt it to various usages and conditions.

What is claimed is:

1. An LED lighting unit comprising:
a first carrier plate;
an LED package in thermal communication with the first carrier plate; and
a PWB disposed on the first carrier plate and in electrical communication with the LED package, wherein the PWB is spaced from at least a portion of the LED package.

2. The LED lighting unit according to claim 1, wherein the LED package includes an LED die disposed on a second carrier plate, a plurality of conductive traces providing electrical communication between the LED die and a secondary wire bond surface, and a dome covering the LED die.

3. The LED lighting unit according to claim 2, wherein the LED die is in thermal communication with the second carrier plate.

4. The LED lighting unit according to claim 3, wherein the second carrier plate is in thermal communication with the first carrier plate.

5. The LED lighting unit according to claim 1, wherein the PWB is spaced from the entire LED package.

6. The LED lighting unit according to claim 5, further comprising an aperture formed in the PWB adapted to receive the LED package therein.

7. The LED lighting unit according to claim 6, further comprising an aperture formed in the PWB adapted to receive an optical lens therein.

8. The LED lighting unit according to claim 1, wherein electrical communication between the LED package and the PWB is provided by one of wire bonding, ball bonding, and ribbon bonding.

9. The LED lighting unit according to claim 1, further comprising a surface-mount device connector disposed on the PWB, the surface-mount device connector in electrical communication with the PWB.

10. An LED lighting unit comprising:
a first carrier plate;
an LED package in thermal communication with the first carrier plate;
a PWB disposed on the first carrier plate and in electrical communication with the LED package, wherein the PWB is spaced from at least a portion of the LED package; and
a surface-mount device connector disposed on the PWB, the surface-mount device connector in electrical communication with the PWB.

11. The LED lighting unit according to claim 10, wherein the LED package includes an LED die disposed on a second carrier plate, a plurality of conductive traces providing electrical communication between the LED die and a secondary wire bond surface, and a dome covering the LED die.

12. The LED lighting unit according to claim 11, wherein the LED die is in thermal communication with the second carrier plate.

13. The LED lighting unit according to claim 12, wherein the second carrier plate is in thermal communication with the first carrier plate.

14. The LED lighting unit according to claim 10, further comprising an aperture formed in the PWB adapted to receive the LED package therein.

15. The LED lighting unit according to claim 10, wherein electrical communication between the LED package and the PWB is provided by one of wire bonding, ball bonding, and ribbon bonding.

16. A method for maximizing heat transfer in an LED lighting unit, the method comprising the steps of:
providing an LED package;
attaching the LED package to a first carrier plate to provide thermal communication between the LED package and the first carrier plate;
disposing a PWB on the first carrier plate, wherein the PWB is at least partially spaced from the LED package; and
providing electrical communication between the PWB and the LED package.

17. The method according to claim 16, wherein the LED package includes an LED die disposed on a second carrier plate, a plurality of conductive traces providing electrical communication between the LED die and a secondary wire bond surface, and a dome covering the LED die.

18. The method according to claim 16, wherein the PWB is entirely spaced from the LED package.

19. The method according to claim 16, wherein the LED package extends through an aperture formed in the PWB.

20. The method according to claim 16, wherein electrical communication between the LED package and the PWB is provided by one of wire bonding, ball bonding, and ribbon bonding.
